(19) United States
(12) Patent Application Publication
(10) Pub. No.: US 2006/0032622 A1
(43) Pub. Date: Feb. 16, 2006

(54) Thermal assembly and method for fabricating the same

(75) Inventors: Shih-Chien Yen, Tu-Cheng (TW); Kuo-Lung Lin, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/198,544

(22) Filed: Aug. 5, 2005

(30) Foreign Application Priority Data
Aug. 11, 2004 (CN) 200410051098.X

(51) Int. Cl. H05K 7/20

(52) U.S. Cl. 165/185; 165/80.3; 361/705

(57) ABSTRACT

A thermal assembly includes a heat source (10), a heat sink (50), a thermal interface material (30) and a porous membrane (20). The heat sink is over the heat source. The thermal interface material is enclosed with the porous membrane, with both being between the heat source and the heat sink. The porous membrane has a number of holes (23a) in which a number of carbon nanotubes (28) are provided. A method for fabricating the thermal assembly includes the following steps. The heat source having a surface is provided, wherein the surface defines a central part. The thermal interface material is coated onto the central part of the surface of the heat source. The thermal interface material is enclosed with the porous membrane, the porous membrane having the holes in which the carbon nanotubes are provided. The heat sink is attached to the heat source.

### FIELD OF THE INVENTION

The invention relates generally to thermal assemblies for transferring unwanted heat; and more particularly to a thermal assembly having a thermal interface material.

### BACKGROUND

Nowadays semiconductor devices are smaller and run faster than ever before. These devices also generate more heat than ever before. A semiconductor device should be kept within its operational temperature limits to ensure good performance and reliability. Typically, a heat sink is attached to a surface of the semiconductor device. Heat is transferred from the semiconductor device to ambient air via the heat sink. When attaching the heat sink to the semiconductor device, respective surfaces thereof are brought together into direct contact. In such contact, however, as much as 99% of the respective surfaces are separated by a layer of interstitial air. Therefore, a thermal interface material is used to eliminate air gaps from a thermal interface and to improve heat flow through the thermal interface.

U.S. Pat. No. 6,451,422 discloses a thermal interface material composition that comprises rubber, a phase change material, and a thermally conductive filler. The thermally conductive filler comprises particles of materials of high thermal conductivity dispersed in the phase change material. However, when the thermal interface material conducts heat from a chip to a heat sink, the thermal interface material is prone to volatilize or seep out, thereby leaving gaps between the heat sink and the chip. The gaps increase and destabilize the contact thermal resistance between the heat sink and the chip. In addition, the seepage of thermal interface material may cause short circuiting.

A new thermal assembly which overcomes the above-mentioned problems and a method for manufacturing such thermal assembly are desired.

### SUMMARY

A thermal assembly includes a heat source, a heat sink, a thermal interface material, and a porous membrane. The heat sink is over the heat source. The thermal interface material is enclosed with the porous membrane, with both being between the heat source and the heat sink. The porous membrane has a plurality of holes in which a plurality of carbon nanotubes are provided.

A method for fabricating the thermal assembly includes the following steps:

(a) The heat source having a surface is provided, wherein the surface defines a central part.

(b) The thermal interface material is coated onto the central part of the surface of the heat source.

(c) The thermal interface material is enclosed with the porous membrane, the porous membrane having the holes in which the carbon nanotubes are provided.

(d) The heat sink is attached to the heat source, thereby pressing the porous membrane between the heat sink and the heat source.

In the above-described method of fabricating the thermal assembly, the porous membrane having the carbon nanotubes is made as follows. A metal plate is partially oxidized by being anodized in an electrobath, so that the metal plate becomes an oxidized metal plate adjoining a non-oxidized metal plate. The oxidized metal plate defines a plurality of recesses, and includes a barrier layer portion under the recesses. The non-oxidized metal plate is removed from the oxidized metal plate. The recesses of the oxidized metal plate are overfilled with a gel. The barrier layer portion is removed, thereby leaving the oxidized metal plate serving as the porous membrane defining the holes. The holes of the porous membrane are overfilled with the gel. A metal catalyst is added up to the porous membrane. The gel is removed from the holes of the porous membrane. The carbon nanotubes are formed in the holes of the porous membrane. The metal catalyst is removed from the porous membrane.

The thermal assembly includes the porous membrane enclosing the thermal interface material, with both the porous membrane and the thermal interface material being between the heat sink and the heat source. This enclosure prevents the thermal interface material from volatilizing or seeping out, so that gaps are not formed between the heat sink and the heat source. Additionally, the carbon nanotubes in the holes of the porous membrane have excellent thermal conductivity, thereby decreasing the contact thermal resistance of the thermal interface material between the heat sink and the heat source.

Other advantages and novel features will become more apparent from the following detailed description when taken in conjunction with the accompanying drawings, in which:

### BRIEF DESCRIPTION OF THE DRAWINGS

FIG. 1 is a schematic, cross-sectional view of a thermal assembly having a thermal interface material and a porous membrane according to a preferred embodiment of the present invention, showing the thermal assembly sandwiched between a heat source and a heat sink;

FIG. 2 is a cross-sectional view of the thermal assembly of FIG. 1, corresponding to line II-II thereof;

FIG. 3 through FIG. 10 are schematic, cross-sectional views of successive steps in a process for making the porous membrane of the thermal assembly, with FIG. 10 showing the finished porous membrane.

### DETAILED DESCRIPTION OF PREFERRED EMBODIMENTS

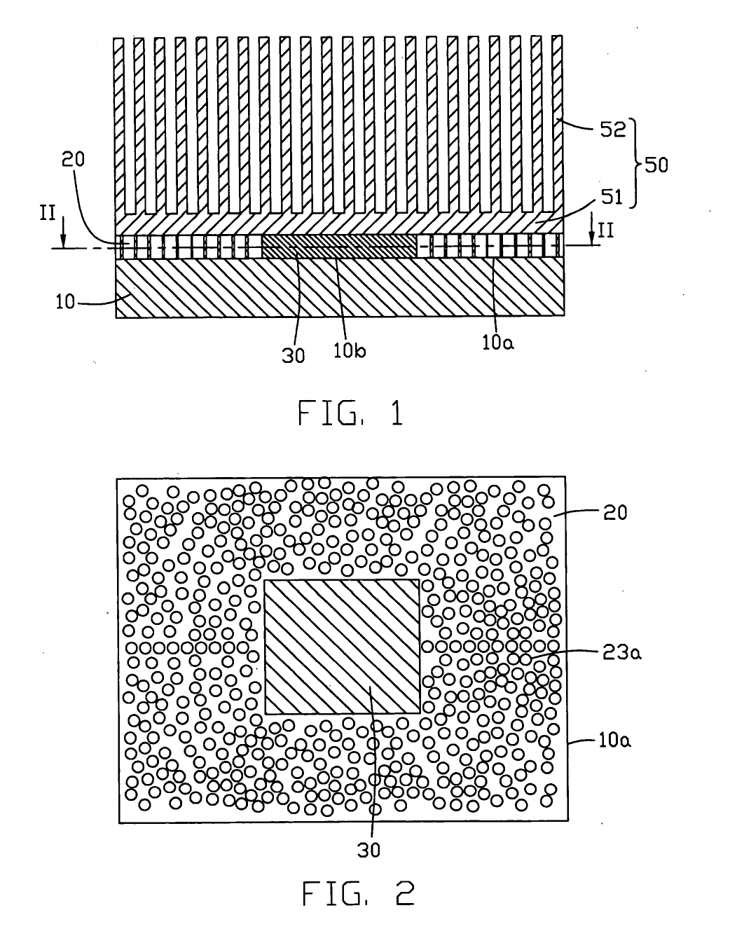

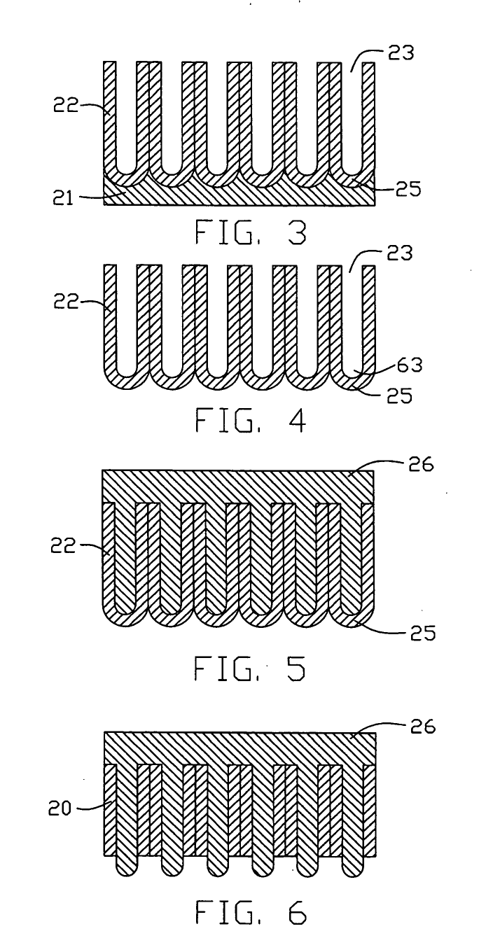

Referring to FIG. 1 and FIG. 2, in one aspect, a thermal assembly includes a heat source 10, a heat sink 50, a thermal interface material 30 and a porous membrane 20. The heat sink 50 is located over the heat source 10. The thermal interface material 30 is enclosed by the porous membrane 20, with the thermal interface material 30 and the porous membrane 20 being between the heat source 10 and the heat sink 50. The porous membrane 20 is capable of becoming a thermal conductive member by having a plurality of holes 23a, in which a plurality of carbon nanotubes 28 are formed (see FIG. 10).

The heat source 10 is, for example, a central processing unit (CPU). Alternatively, the heat source 10 may, for example, be an electronic device such as a power transistor, a video graphics array (VGA) module, or a radio frequency integrated circuit (RFIC).

The heat sink 10 may have, for example, a fan-cooling configuration, a water-cooling configuration, or a heat-pipe configuration. In this embodiment, the heat sink 10 has a fan-cooling configuration. The heat sink 10 has a base 51 and fins 52 both made of aluminum. Alternatively, the base 51 may be made of copper. In such case, the copper base 51 is connected to the aluminum fins 52 by technologies such as shaping, welding, soft soldering, hard soldering, diffusion connecting, rolling, laser soldering, plastic deformation, or metal-powder sintering. Alternatively, the copper base 51 can be connected to the aluminum fins 52 by a medium such as a thermally conductive adhesive or a thermally conductive grease.

The thermal interface material 30 may be a thermally conductive adhesive, a thermally conductive grease, a phase change material, or a material filled with metal powder, carbon nanotubes or other materials having high thermal conductivities.

In another aspect, a method of fabricating the thermal assembly includes the following steps:

(a) The heat source 10 having a surface 10a is provided, wherein the surface 10a has a central part 10b.

(b) The thermal interface material 30 is coated onto the central part 10b of the surface 10a of the heat source 10.

(c) The thermal interface material 30 is enclosed by the porous membrane 20, the porous membrane 20 having the holes 23a in which the carbon nanotubes 28 are formed (see FIG. 10).

(d) The heat sink 50 is attached to the heat source 10, thereby pressing the porous membrane 20 between the heat sink 50 and the heat source 10.

In the above-described method of fabricating the thermal assembly, the porous membrane 20 having the carbon nanotubes 28 is made by the following steps:

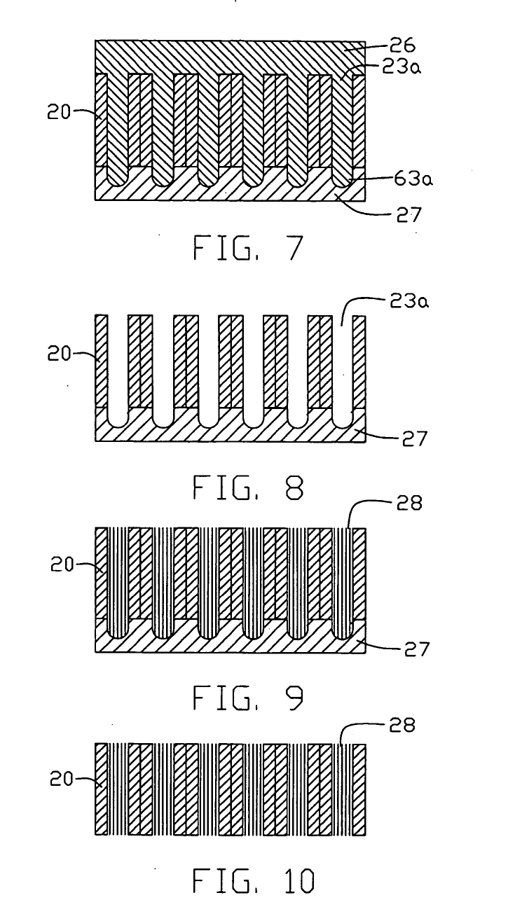

(a) Referring to FIG. 3, a metal plate, such as an aluminum plate, is partially oxidized by being anodized in an electrobath. The electrobath may be an oxalic acid solution provided at a temperature of about 15±1 degrees Celsius, and having a concentration of about 0.4 mol/L. The metal plate is anodized by applying a current to the electrobath, the current having a current density of about 72 mA per square centimeter, and the anodizing taking place at room temperature. The metal plate is oxidized to become an oxidized metal plate 22 adjoining a non-oxidized metal plate 21. The oxidized metal plate 22 has a thickness of about 200 micrometers. The oxidized metal plate 22 defines a plurality of recesses 23, and includes a barrier layer portion 25 under the recesses 23. Each of the recesses 23 has a diameter of about 100 nanometers. The electrobath may alternatively be a sulfuric acid solution or a phosphoric acid solution.

(b) Referring to FIG. 4, the non-oxidized metal plate 21 is removed from the oxidized metal plate 22 by immersion in mercury chloride or muriatic acid. After the removing step, the barrier layer portion 25 of the oxidized metal plate 22 is exposed. The exposed barrier layer portion 25 covers one end portion 63 of each of the recesses 23.

(c) Referring to FIG. 5, the recesses 23 of the oxidized metal plate 22 are overfilled with a gel 26.

(d) Referring to FIG. 6, the barrier layer portion 25 is removed by immersion in sulfuric acid or phosphoric acid. Remaining portions of the oxidized metal plate 20 serve as the porous membrane 20, and remaining portions of the recesses 23 are defined as the holes 23a of the porous membrane 20. The holes 23a of the porous membrane 20 remain overfilled with the gel 26.

(e) Referring to FIG. 7, a metal catalyst 27 is attached to the porous membrane 20. The metal catalyst 27 is plated onto an underside of the porous membrane 20 where the gel 26 is exposed. Thus the metal catalyst 27 covers end portions 63a of the gel 26. The metal catalyst 27 has a thickness in the range of about 1 to about 99 nanometers, and may include iron, cobalt, nickel, or any alloy thereof.

(f) Referring to FIG. 8, the gel 26 is removed from the holes 23a of the porous membrane 20. The gel 26 may be removed by using a wet-etching recipe.

(g) Referring to FIG. 9, the carbon nanotubes 28 are formed in the holes 23a of the porous membrane 20 by chemical vapor deposition. In the chemical vapor deposition, preferably, ethylene serves as a gaseous carbon source, iron serves as the metal catalyst 27, and the carbon nanotubes 28 are formed at a temperature in the range of about 650 to about 700 degrees Celsius.

(h) Referring to FIG. 10, the metal catalyst 27 (FIG. 9) is removed from the porous membrane 20 by a dry etching technology or a wet etching technology. In the step of removal of the metal catalyst 27, bottom portions of the carbon nanotubes 28 are also removed to leave the carbon nanotubes 28 level with a bottom surface of the porous membrane 20. The porous membrane 20 having the carbon nanotubes 28 is thus obtained.

The previously described aspects of the present invention have many advantages. For example, the thermal assembly includes the porous membrane enclosing the thermal interface material, with both the porous membrane and the thermal interface material being between the heat sink and the heat source. This enclosure prevents the thermal interface material from volatilizing or seeping out, so that gaps are not formed between the heat sink and the heat source. Additionally, the carbon nanotubes, formed in the holes of the porous membrane, have excellent thermal conductivity, thereby decreasing the contact thermal resistance of the thermal interface material between the heat sink and the heat source.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

We claim:

1. A thermal assembly comprising:
a heat source;
a heat sink over the heat source;
a thermal interface material between the heat source and the heat sink; and
a porous membrane enclosing the thermal interface material, wherein the porous membrane has a plurality of holes in which a plurality of carbon nanotubes are provided.

2. The thermal assembly of claim 1, wherein the porous membrane has a thickness in the range of about 1 to about 200 micrometers.

3. The thermal assembly of claim 1, wherein the porous membrane comprises an oxidized metal plate.

4. A method for fabricating a thermal assembly, the method comprising:
providing a heat source having a surface, wherein the surface defines a central part;
coating a thermal interface material onto the central part of the surface of the heat source;
enclosing the thermal interface material with a porous membrane, wherein the porous membrane has a plurality of holes in which a plurality of carbon nanotubes are provided; and
attaching a heat sink to the heat source, thereby pressing the porous membrane between the heat sink and the heat source.

5. The method of claim 4, further comprising:
partially oxidizing a metal plate by anodizing the metal plate in an electrobath, so that an oxidized metal plate adjoining a non-oxidized metal plate is obtained, the oxidized metal plate comprising a plurality of recesses and a barrier layer portion under the recesses;
removing the non-oxidized metal plate from the oxidized metal plate;
overfilling the recesses of the oxidized metal plate with a gel;
removing the barrier layer portion, thereby leaving a porous membrane defining holes, the holes of the porous membrane being overfilled with the gel;
attaching a metal catalyst to the porous membrane;
removing the gel from the holes of the porous membrane;
forming carbon nanotubes in the holes of the porous membrane; and
removing the metal catalyst from the porous membrane.

6. The method of claim 5, wherein the metal plate comprises aluminum.

7. The method of claim 5, wherein the porous membrane has a thickness in the range of about 1 to about 200 micrometers.

8. The method of claim 5, wherein the metal catalyst has a thickness in the range of about 1 to about 99 nanometers.

9. The method of claim 5, wherein the metal catalyst is selected from the group consisting of iron, cobalt, nickel, and any combination thereof.

10. A method for fabricating a thermal assembly, comprising the steps of:
preparing a thermal contact surface on a heat source of a thermal assembly;
placing a thermal interface material on said surface by means of spacing said thermal interface material away from edges of said surface;
disposing a thermal conductive member surrounding said thermal interface material along said edges of said surface so as to block moving ways of said thermal interface material toward said edges of said surface; and
attaching a heat dissipating device onto said thermal conductive member and said thermal interface material simultaneously to establish thermal transmission with said heat source via said thermal conductive member and said thermal interface material.

11. The method of claim 10, wherein said thermal conductive member comprises a porous membrane surrounding said thermal interface material.

12. The method of claim 10, wherein said thermal conductive member has a plurality of holes in which a plurality of carbon nanotubes are provided.
